(19) United States
(12) Patent Application Publication
(10) Pub. No.: US 2021/0078783 A1
(43) Pub. Date: Mar. 18, 2021

(54) STUD, SUBSTRATE UNIT, AND CARRIER TAPE

(71) Applicant: FUJITSU CLIENT COMPUTING LIMITED, Kanagawa (JP)

(72) Inventors: Yuki Takahashi, Kawasaki (JP); Masuo Ohnishi, Kawasaki (JP)

(73) Assignee: FUJITSU CLIENT COMPUTING LIMITED, Kanagawa (JP)

(21) Appl. No.: 16/930,460

(22) Filed: Jul. 16, 2020

(30) Foreign Application Priority Data
Sep. 13, 2019 (JP) 2019-167322

(51) Int. Cl. B65D 73/02; F16B 19/00; H05K 1/18

(52) U.S. Cl. CPC B65D 73/02; H05K 1/115; H05K 1/181; F16B 19/00

(57) ABSTRACT

A stud includes a base and a protrusion. The base includes a second screw that engages with a first screw, and is to be joined to a first face of an attachment plate. The protrusion has a non-circular shape as viewed from a first direction intersecting the attachment plate and protrudes from the base in the first direction to be inserted into an opening in the attachment plate.

### CROSS-REFERENCE TO RELATED APPLICATIONS

This application is based upon and claims the benefit of priority from Japanese Patent Application No. 2019-167322, filed Sep. 13, 2019, the entire contents of which are incorporated herein by reference.

### FIELD

Embodiments described herein relate generally to a stud, a substrate unit, and a carrier tape.

### BACKGROUND

Conventionally, studs have been known, which include a base provided with a female screw that engages with a male screw, and to be jointed to the top face of a substrate; and a protrusion protruding from the base in a first direction intersecting the substrate and to be inserted into an opening of the substrate.

Substrate units including a substrate and an attachment plate to which studs are coupled have been also known.

It may be beneficial to provide a stud of a novel, improved structure with less inconvenience that can be restricted from rotating relative to the attachment plate or substrate regardless of rotation torque applied from fastening the screws.

It is preferable to provide a stud of a novel, improved structure with less inconvenience, and a substrate unit and a carrier tape.

### SUMMARY

According to one aspect of this disclosure, a stud includes a base and a protrusion. The base includes a second screw that engages with a first screw, and is to be joined to a first face of an attachment plate. The protrusion has a non-circular shape as viewed from a first direction intersecting the attachment plate and protrudes from the base in the first direction to be inserted into an opening in the attachment plate.

### BRIEF DESCRIPTION OF THE DRAWINGS

FIG. 1 is an illustrative and schematic perspective view of a substrate unit on which studs are mounted according to one or more embodiments;

FIG. 2 is an illustrative and schematic plan view of the substrate unit having the studs mounted thereon in one or more embodiments, as viewed from a direction opposite to a Z-direction;

FIG. 3 is a sectional view of FIG. 2 taken along the III-III line;

FIG. 4 is an illustrative and schematic plan view of the substrate unit having the studs mounted thereon in one or more embodiments, as viewed from a Z-direction;

FIG. 5 is an enlarged view of the region denoted by a letter V in FIG. 4;

FIG. 6 is an illustrative and schematic plan view of a first stud according to one or more embodiments, as viewed from the direction opposite to the Z-direction;

FIG. 7 is an illustrative and schematic plan view of the first stud of one or more embodiments, as viewed from the Z-direction;

FIG. 8 is an illustrative and schematic side view of the first stud of one or more embodiments, as viewed from a direction opposite to an X-direction;

FIG. 9 is an illustrative and schematic side view of the first stud of one or more embodiments, as viewed from a Y-direction;

FIG. 10 is an illustrative and schematic plan view of a second stud of one or more embodiments, as viewed from the direction opposite to the Z-direction;

FIG. 11 is an illustrative and schematic plan view of the second stud of one or more embodiments, as viewed from the Z-direction;

FIG. 12 is an illustrative and schematic side view of the second stud of one or more embodiments, as viewed from the direction opposite to the X-direction;

FIG. 13 is an illustrative and schematic plan view of a third stud according to one or more embodiments, as viewed from the direction opposite to the Z-direction;

FIG. 14 is an illustrative and schematic plan view of the third stud of one or more embodiments, as viewed from the Z-direction;

FIG. 15 is an illustrative and schematic side view of the third stud of one or more embodiments, as viewed from the direction opposite to the X-direction;

FIG. 16 is an illustrative and schematic plan view of a carrier tape containing the studs according to one or more embodiments housed therein;

FIG. 17 is a sectional view of FIG. 16 taken along the XVII-XVII line;

FIG. 18 is a sectional view of FIG. 17 taken along the XVIII-XVIII line;

FIG. 19 is an illustrative and schematic plan view of a stud according to a modification, as viewed from the direction opposite to the Z-direction;

FIG. 20 is an illustrative and schematic plan view of the stud of the modification, as viewed from the Z-direction;

FIG. 21 is an illustrative and schematic side view of the stud of the modification, as viewed from a direction opposite to the X-direction; and

FIG. 22 is an illustrative and schematic side view of the stud of the modification, as viewed from the Y-direction.

### DETAILED DESCRIPTION OF EMBODIMENTS

The following will disclose one or more embodiments and a modification by way of example. The features of the following embodiments and modification as well as action and effects attained by the features are presented for illustrative purpose only, and not intended to limit the scope of the present invention. The embodiments and modification can be implemented by features other than those disclosed herein. The embodiments and modification can attain at least one of various effects including derivative effects by such features.

The embodiments and modification disclosed below include same or similar constituent elements. Such same or similar constituent elements are denoted by common reference numerals, and overlapping description thereof will be avoided. Throughout this disclosure, ordinal numbers are used for distinguishing parts, components, members, regions, positions, locations, directions, etc., and are not intended to indicate order or priority.

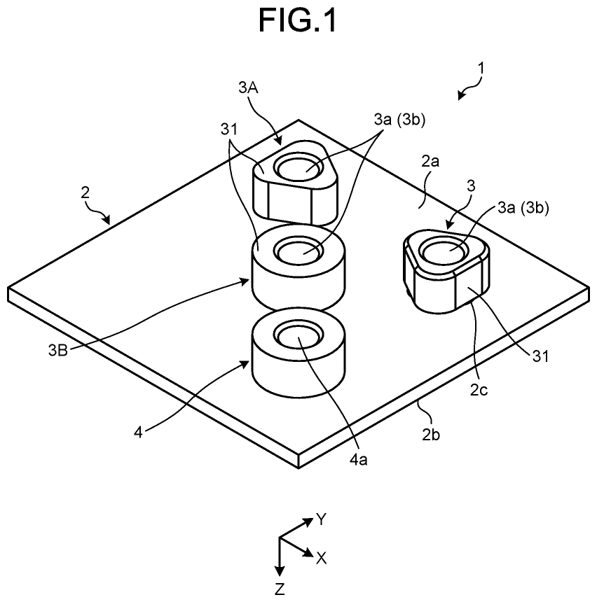

FIG. 1 is a perspective view of a substrate unit 1 on which studs 3, 3A, and 3B are mounted according to one or more embodiments. As illustrated in FIG. 1, the substrate unit 1 includes, for example, a substrate 2, a plurality of studs 3, 3A, and 3B, and a stud 4.

The studs 3, 3A, and 3B and the stud 4 are joined to or unified with the substrate 2, for example, by soldering. The substrate 2 is an exemplary attachment plate. The stud 4 is different from the studs 3, 3A, and 3B each provided with a rotation-stop structure as described below, and the substrate unit 1 may not be provided with the stud 4.

In the following, three directions perpendicular to one another are defined for the sake of convenience. An X-direction is along the longitudinal (front to back direction) width of the substrate 2; a Y-direction is along the transverse (horizontal direction) width of the substrate 2; and a Z-direction is along the thickness (vertical direction) of the substrate 2. The X-direction and the Y-direction are the radial directions of the studs 3, 3A, 3B, and 4; and the Z-direction is along the axes of the studs 3, 3A, 3B, and 4.

The Z-direction is an exemplary first direction intersecting the substrate 2. For the sake of convenience, in the following, the X-direction is also referred to as forward; a direction opposite to the X-direction also as rearward; the Y-direction also as leftward; a direction opposite to the Y-direction also as rightward; the Z-direction also as downward; and a direction opposite to the Z-direction also as upward.

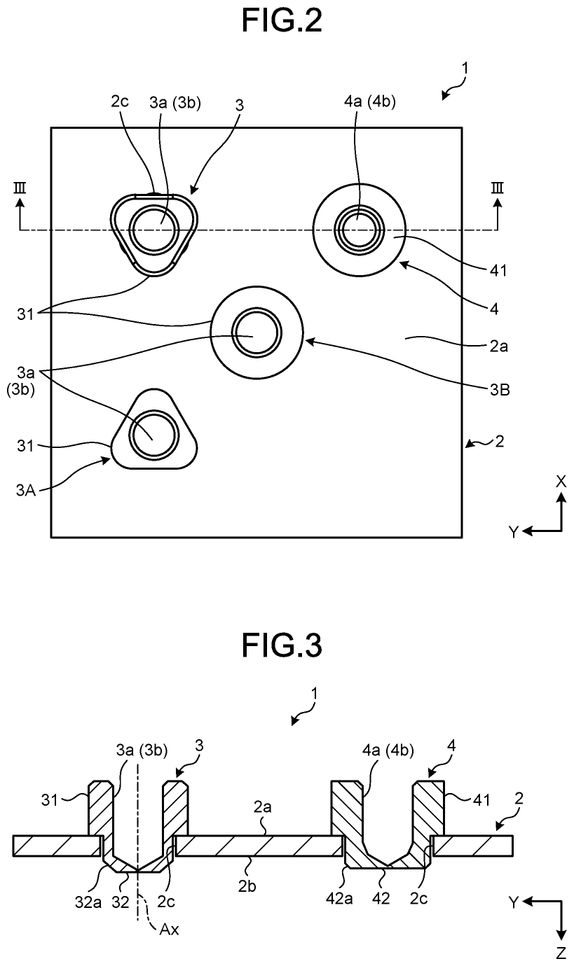

FIG. 2 is a plan view of the substrate unit 1, as viewed from a direction opposite to the Z-direction; and FIG. 3 is a sectional view of FIG. 2 taken along the III-III line. As illustrated in FIGS. 2 and 3, the substrate 2 has a top face 2a facing the direction opposite to the Z-direction, and a bottom face 2b facing the Z-direction. A plurality of electronic components (not illustrated), such as a central processing unit (CPU), a read only memory (ROM), and a random access memory (RAM), is mounted on the top face 2a and the bottom face 2b, for example.

In one or more embodiments, the substrate unit 1 is incorporated in an electronic device, and these electronic components and a wiring pattern 5 (see FIG. 5) in the substrate 2 forms at least part of control circuitry of the electronic device. Examples of the electronic device include a clamshell (laptop) personal computer, a tablet personal computer, and a smartphone.

In one or more embodiments, the studs 3, 3A, and 3B and the stud 4 are individually provided with female screws 3a and 4a. Male screws (not illustrated), serving as fasteners for fixing an electronic component such as a heatsink, engage with the female screws 3a and 4a, for example. The male screws are exemplary first screws, and the female screws 3a are exemplary second screws.

The studs 3, 3A, and 3B are not limited to this example and may be, for example, stud bolts including a male screw as a second screw. The studs 3, 3A, and 3B may be referred to also as female screw studs, securing members, or screw members.

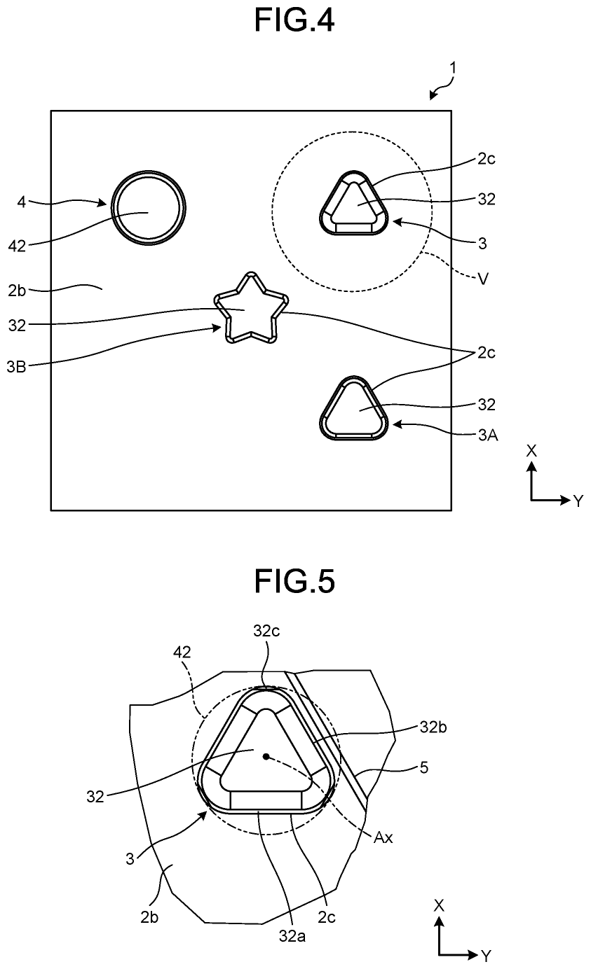

FIG. 4 is a plan view of the substrate unit 1, as viewed from the Z-direction; and FIG. 5 is an enlarged view of the region denoted by a letter V in FIG. 4. As illustrated in FIGS. 3 to 5, the studs 3, 3A, and 3B each include a base 31 and a protrusion 32, and the stud 4 includes a base 41 and a protrusion 42, for example. There is a step (on an XY-plane) lying between the bases 31 and 41 and the corresponding protrusions 32 and 42 in the radial direction.

The top face 2a of substrate 2 is provided with through-holes 2c, and the bases 31 and 41 are supported by the peripheries of the through-holes 2c. That is, the bases 31 and 41 are larger in diameter than the through-holes 2c. The bases 31 and 41 are joined to the top face 2a by soldering, for example. The top face 2a is an exemplary first face. The bases 31 and 41 are also referred to as heads or first parts, for example. The bases 31 and 41 and the protrusions 32 and 42 are made of, for example, a metal material such as brass or aluminum.

The protrusions 32 and 42 protrude from the bases 31 and in the Z-direction and are inserted into the corresponding through-holes 2c of the substrate 2. The protrusions 32 and 42 are smaller in diameter than the corresponding bases 31 and 41. The protrusions 32 and 42 are joined to the peripheries of the corresponding through-holes 2c in the bottom face 2b of the substrate 2 by soldering. Each of the through-holes 2c is an exemplary opening. The protrusions 32 and 42 are referred to also as insertions, shafts, extensions, or second parts.

The bases 31 and 41 and the protrusions 32 and 42 are provided with central holes 3b and 4b extending in the Z-direction. The Z-directional ends of the central holes 3b and 4b are closed while the opposite ends thereof are open. The inner surfaces of the central holes 3b and 4b are provided with female screws 3a and 4a. That is, the female screws 3a and 4a extend through the bases 31 and 41 and the protrusions 32 and 42, respectively.

In one or more embodiments, the protrusions 32 of the studs 3, 3A, and 3B have a non-circular shape as viewed from the Z-direction (see FIGS. 4 and 5). Specifically, the protrusions 32 have a polygonal shape in the Z-direction. In contrast, the protrusion 42 of the stud 4 has a circular shape as viewed from the Z-direction.

In one or more embodiments, the through-holes 2c of the substrate 2 have non-circular shapes conforming to the shapes of the protrusions 32 of the corresponding studs 3, 3A, and 3B. The protrusions 32 are engaged with or fitted into the corresponding through-holes 2c. In this manner, the studs 3, 3A, and 3B are restricted from rotating relative to the substrate 2 due to rotation torque occurring from fastening the male screws and the female screws 3a together. The protrusions 32 and the periphery of the through-holes 2c serve as an exemplary rotation-stop structure.

In one or more embodiments, the respective protrusions of the studs 3, 3A, and 3B and the through-holes 2c corresponding to the protrusions 32 are smaller in size than the protrusion 42 of the stud 4 and the through-hole 2c corresponding to the protrusion 42. The protrusion 32 can be formed by, for example, whittling the radially outer circumference of the protrusion 42 into a polygonal shape.

As illustrated in FIG. 5, in one or more embodiments, the radius of the protrusion 42 is substantially equal to the distance between a rotational center Ax of the protrusion 32 and the vertex of each corner 32c, for example. The distance between each side 32b of the protrusion 32 and the rotational center Ax is shorter than the radius of the protrusion 42.

The protrusion 32 has a sloping face 32a. The sloping face 32a is formed by, for example, chamfering each corner of the Z-directional end of the protrusion 32. As illustrated in FIG. 3, the sloping face 32a tilts to be closer to the rotational center Ax in the Z-direction. The sloping face 32a is referred to also as a chamfer face, a tapered face, or a guiding face.

In one or more embodiments, the radial width (on an XY-plane) of the sloping face 32a is larger than the radial width of a sloping face 42a of the protrusion 42. Specifically, the width of the sloping face 32a is set twice or more as large as the width of the sloping face 42a.

In one or more embodiments, thus, the sloping face 32a is set to have a relatively large radial width, which leads to prevent the protrusion 32 from being misaligned with the through-hole 2c about the rotational center Ax and improves insertability of the protrusion 32 into the through-hole 2c.

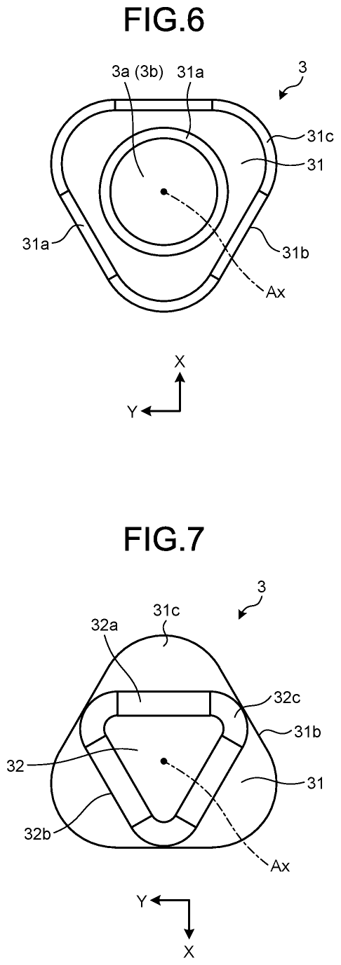

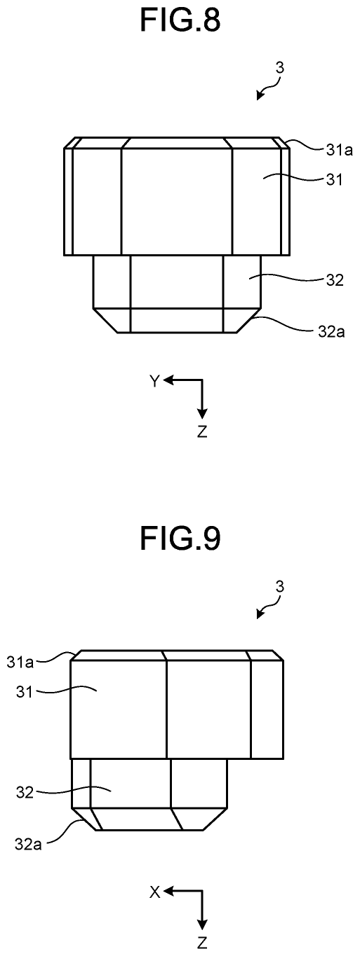

Next, the shapes of the studs 3, 3A, and 3B are described in detail. FIG. 6 is a plan view of the stud 3, as viewed from the direction opposite to the Z-direction; FIG. 7 is a plan view of the stud 3, as viewed from the Z-direction; FIG. 8 is a side view of the stud 3, as viewed from the X-direction; and FIG. 9 is a side view of the stud 3, as viewed from the Y-direction.

As illustrated in FIGS. 6 to 9, the stud 3 includes, for example, the base 31 and the protrusion 32. The base 31 and the protrusion 32 have a regular triangular prism shape as a whole, extending in the Z-direction. The protrusion 32 is smaller in diameter than the base 31.

As illustrated in FIG. 7, the protrusion 32 is set in an inverted posture relative to the base 31 in the X-direction, as viewed from the Z-direction. That is, the corners 32c of the protrusion 32 are offset at 60 degrees from corners 31c of the base 31 in a circumferential direction about the rotational center Ax.

As illustrated in FIG. 6, the base 31 has sloping faces 31a. The sloping faces 31a are formed by, for example, chamfering the corners of the radially outer and inner circumferences of the base 31 in the direction opposite to the Z-direction. The sloping faces 31a are referred to also as chamfered faces, tapered faces, or guiding faces.

In one or more embodiments, the inner-side sloping face 31a can work to improve the insertability of a fastener, such as a bolt, into the central hole 3b. In one or more embodiments, as illustrated in FIGS. 6 to 9, the sloping faces 32a of the protrusion 32 are set larger in width than the sloping faces 31a in the radial direction.

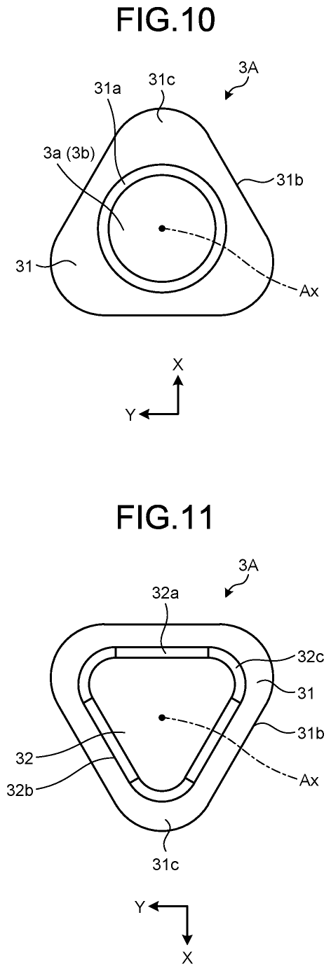

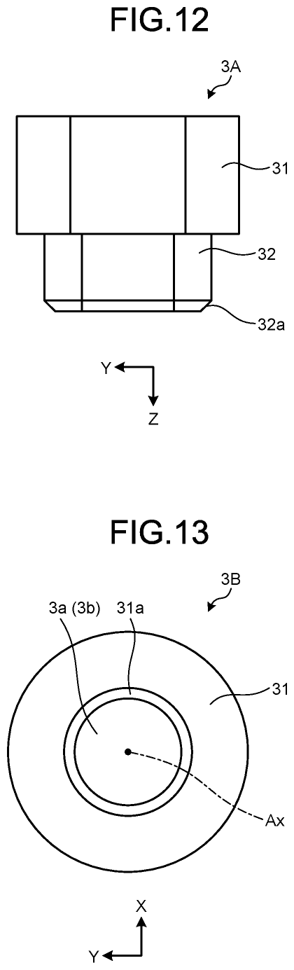

FIG. 10 is a plan view of the stud 3A, as viewed from the direction opposite to the Z-direction; FIG. 11 is a plan view of the stud 3A, as viewed from the Z-direction; and FIG. 12 is a side view of the stud 3A, as viewed from the direction opposite to the X-direction.

As illustrated in FIGS. 10 to 12, the stud 3A includes, for example, the base 31 and the protrusion 32. The base 31 and the protrusion 32 have a regular triangular prism shape as a whole, extending in the Z-direction. The protrusion 32 is smaller in diameter than the base 31.

As illustrated in FIG. 11, the protrusion 32 and the base 31 are set in the same posture, as viewed from the Z-direction. That is, the corners 32c of the protrusion 32 are not offset from but aligned with the corners 31c of the base 31 in a circumferential direction about the rotational center Ax.

As illustrated in FIG. 10, the radially inner circumference of the base 31 includes the sloping face 31a. The sloping face 31a is not limited to this example and another sloping face may be included in, for example, the radially outer circumference of the base 31. The radial width of the sloping face 31a is narrower than the radial width of the sloping face 32a of the protrusion 32.

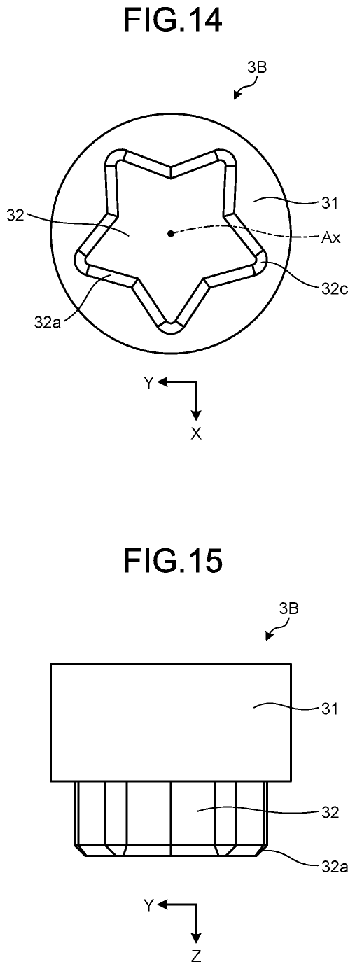

FIG. 13 is a plan view of the stud 3B, as viewed from the direction opposite to the Z-direction; FIG. 14 is a plan view of the stud 3B as viewed from the Z-direction; and FIG. 15 is a side view of the stud 3B as viewed from the direction opposite to the X-direction.

As illustrated in FIGS. 13 to 15, the stud 3B includes, for example, the base 31 and the protrusion 32. The base 31 has a columnar shape as a whole, extending in the Z-direction. The protrusion 32 has a star-form columnar shape as a whole, extending in the Z-direction. The protrusion 32 is smaller in diameter than the base 31.

As illustrated in FIG. 13, the radially inner circumference of the base 31 includes the sloping face 31a. The shape of the protrusion 32 is not limited to this example and may be, for example, elliptical in the Z-direction.

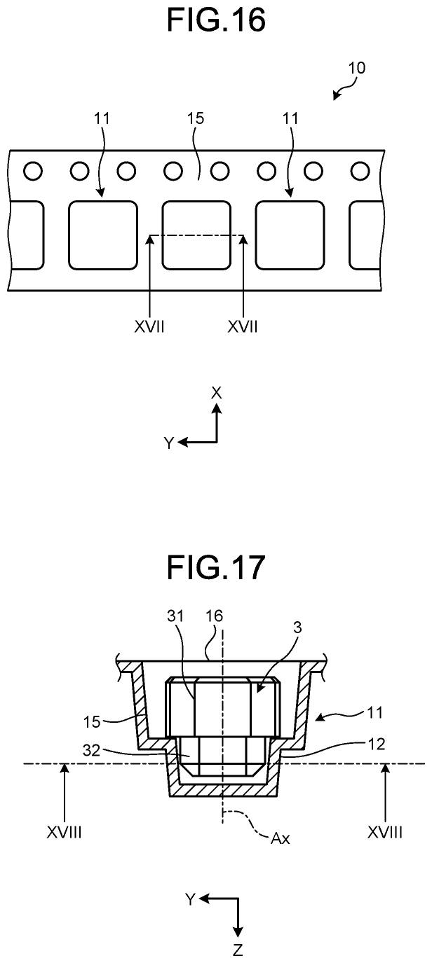

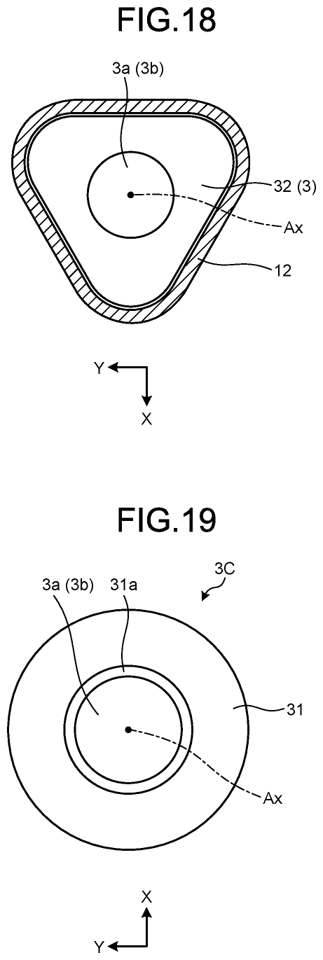

The following describes a carrier tape 10 for use in packaging the studs 3, 3A, and 3B in detail. FIG. 16 is a plan view of the carrier tape 10 containing the studs 3, 3A, and 3B; FIG. 17 is a sectional view of FIG. 16 taken along the XVII-XVII line; and FIG. 18 is a sectional view of FIG. 17 taken along the XVIII-XVIII line.

As illustrated in FIGS. 16 to 18, the carrier tape 10 includes, for example, a base tape 15 and a cover tape 16 (see FIG. 17). The base tape 15 is made of polystyrene resin; and the cover tape 16 is made of polyester resin, for example. The carrier tape 10 is referred to also as an embossed carrier tape.

As illustrated in FIG. 17, the base tape 15 includes a plurality of pockets 11 that can accommodate the studs 3, 3A, and 3B, i.e., electronic components. Each of the pockets 11 is recessed from the top face of the base tape 15 in the Z-direction and opens in the direction opposite to the Z-direction. The cover tape 16 covers the studs 3, 3A, and 3B accommodated in the pockets 11 from the direction opposite to the Z-direction. The base tape 15 is referred to also as a carrier tape body.

Each pocket 11 is provided with a recess 12. The recess 12 is recessed in the Z-direction from the bottom of the pocket 11 and opens in the direction opposite to the Z-direction. The protrusions 32 of the studs 3, 3A, and 3B are inserted into the recesses 12. That is, the recesses 12 are smaller in diameter than the bases 31 of the studs 3, 3A, and 3B.

In one or more embodiments, the recesses 12 have non-circular shapes (a triangular shape in the example of FIG. 18) corresponding to the protrusions 32 of the studs 3, 3A, and 3B. The corresponding protrusions 32 are engaged with or fitted into the recesses 12. The carrier tape 10 may be provided with one recess 12 corresponding to the protrusion 32 of any of the studs 3, 3A, and 3B, or two or more recesses corresponding to two or more of the studs 3, 3A, and 3B.

According to one or more embodiments, as described above, by the contact between the non-circular protrusion 32 and the edge of the recess 12, the stud 3 is restricted from rotating about the rotational center Ax relative to the pocket 11. The edge of the recess 12 is an exemplary rotation stopper. The rotation stopper is not limited to this example and may be a pin located inside the pocket 11, which serves to limit the rotation of the protrusion 32, for example.

As described above, in one or more embodiments, each of the studs 3, 3A, and 3B includes the base 31 that is joined to the top face 2a (first face) of the substrate 2 (attachment plate) and provided with the female screw 3a (second screw) that engages with a male screw (first screw); and the protrusion 32 of a non-circular shape in the Z-direction (first direction) intersecting the substrate 2, protruding from the base 31 in the Z-direction and inserted into a corresponding one of the through-holes 2c (openings) in the substrate 2.

According to such a structure, for example, the through-holes 2c in the substrate 2 corresponding to the protrusions 32 can have non-circular shapes, and the protrusions 32 and the through-holes 2c serve as the rotation-stop structure to restrict the studs 3, 3A, and 3B from rotating relative to the substrate 2. Further, the protrusions 32 and the through-holes 2c of the non-circular form can be made smaller in size than the ones of a circular form, for example. This enables effective use of spaces around the through-holes 2c, which may facilitate higher-density arrangement of components, such as the wiring pattern 5 and electronic components, on the substrate 2.

In one or more embodiments, the bases 31 have non-circular shapes as viewed from the Z-direction. This makes it easier to decrease the studs 3, 3A, and 3B in weight and size than the bases 31 of a circular shape. This further allows effective use of spaces around the bases 31, for example, and may facilitate higher-density arrangement of components, such as the wiring pattern 5 and electronic components, on the substrate 2.

In one or more embodiments, the bases 31 and the protrusions 32 have triangular shapes as viewed from the Z-direction. This makes it possible, for example, to arrange components, such as the wiring pattern 5 (see FIG. 5) and the electronic components, around the bases 31 and the protrusions 32 along the sides 31b and 32b of the bases 31 and the protrusion 32. This may further facilitate higher-density arrangement of electronic components.

In one or more embodiments, the protrusion 32 has a triangular shape as viewed from the Z-direction, and the base 31 has an inverted triangular shape relative to the triangular shape of the protrusion 32, as viewed from the Z-direction (see FIG. 7). This can increase the area, i.e., the exposed area of the bottom surface of the base 31 than the protrusion 32 and the base 31 set in the same posture, for example (see FIG. 11). That is, for example, the opposing area, i.e., the joint area between the base 31 and the top face 2a of the substrate 2 is increased, leading to enhancing the strength of the joint between the stud 3 and the substrate 2.

In one or more embodiments, the substrate unit 1 includes the top face 2a (first face) to which the bases 31 of the studs 3, 3A, and 3B are joined, and the substrate 2 (attachment plate) provided with the through-holes 2c (openings) into which the protrusions 32 are inserted. The through-holes 2c are of non-circular shapes conforming to the shapes of the respective protrusions 32 of the studs 3, 3A, and 3B, as viewed from the Z-direction. Owing to such a structure, for example, the protrusions 32 and the corresponding through-holes 2c of non-circular shapes serve as a rotation-stop structure to restrict the studs 3, 3A, and 3B from rotating relative to the substrate 2 regardless of rotation torque occurring from fastening the screws.

In one or more embodiments, the carrier tape 10 includes the pockets 11 capable of accommodating the studs 3, 3A, and 3B; and the recesses 12 (rotation stoppers) that face the respective protrusions 32 of the studs 3, 3A, and 3B, and contact with the protrusions 32 to restrict the studs 3, 3A, and 3B from rotating about the rotational center Ax in the Z-direction.

According to such a structure, for example, the protrusions 32 and the recesses 12 can serve to restrict the studs 3, 3A, and 3B from rotating relative to the corresponding pockets 11, which results in preventing the protrusions 32 from being misaligned with the corresponding through-holes 2c about the rotational center Ax at the time of mounting the studs 3, 3A, and 3B on the substrate 2 with a mounter.

### Modification

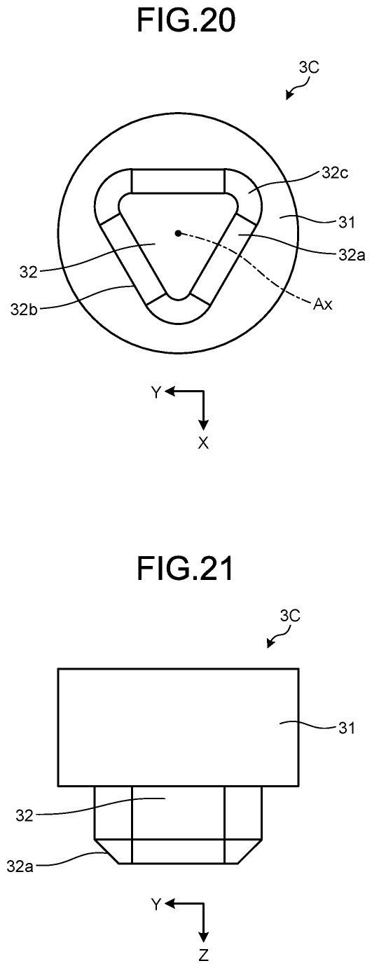

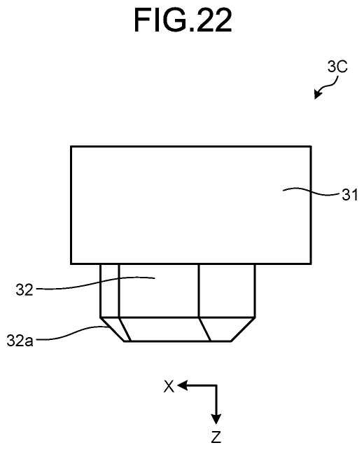

FIG. 19 is a plan view of a stud 3C according to a modification, as viewed from the direction opposite to the Z-direction; FIG. 20 is a plan view of the stud 3C, as viewed from the Z-direction; FIG. 21 is a side view of the stud 3C, as viewed from the X-direction; and FIG. 22 is a side view of the stud 3C, as viewed from the Y-direction.

As illustrated in FIGS. 19 to 22, the stud 3C includes the same structure as the studs 3, 3A, and 3B of the above embodiments. That is, the stud 3C can attain same or like actions and effects based on the same structure as the studs 3, 3A, and 3B.

The present modification, however, differs from the above embodiments in that the base 31 has a round columnar shape extending in the Z-direction and that the protrusion 32 has a regular triangular prism shape extending in the Z-direction, as illustrated in FIGS. 19 to 22. The female screw 3a (central hole 3b) extends through the base 31 and the protrusion 32.

The shape of the protrusion 32 is not limited to this example and can be changed in various manners. According to the present modification, for example, thus, the protrusion 32 and the through-hole 2c of a non-circular shape serve as a rotation-stop structure to restrict the stud 3C from rotating relative to the substrate 2 regardless of rotation torque occurring from fastening the screws.

According to one aspect of this disclosure, it is possible to provide a stud of a novel, improved structure with less inconvenience, and a substrate unit and a carrier tape incorporating such a stud.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. A stud comprising:
a base that joins to a first face of an attachment plate, the base including a second screw that engages with a first screw; and
a protrusion of a non-circular shape as viewed from a first direction intersecting the attachment plate, the protrusion protruding from the base in the first direction to be inserted into an opening in the attachment plate.

2. The stud according to claim 1, wherein
the base has a non-circular shape as viewed from the first direction.

3. The stud according to claim 1, wherein
at least one of the protrusion and the base has a triangular shape as viewed from the first direction.

4. The stud according to claim 1, wherein
the protrusion has a triangular shape as viewed from the first direction, and
the base has an inverted triangular shape relative to the triangular shape of the protrusion, as viewed from the first direction.

5. A substrate unit comprising:
the stud according to claim 1; and
a substrate serving as the attachment plate and including:
the first face that joins to the base of the stud; and
an opening of a non-circular shape conforms to the shape of the protrusion of the stud, as viewed from the first direction, the opening into which the protrusion is inserted.

6. A carrier tape comprising:
a pocket that accommodates the stud according to claim 1; and
a rotation stopper that faces the protrusion of the stud, and contacts with the protrusion to restrict the stud from rotating about a rotational center in the first direction.
